(19) United States
(12) Patent Application Publication
(10) Pub. No.: US 2016/0297671 A1
(43) Pub. Date: Oct. 13, 2016

(54) MEMS Sensor Component

(71) Applicant: EPCOS AG, Muenchen (DE)

(72) Inventor: Wolfgang Pahl, Munchen (DE)

(21) Appl. No.: 14/685,259

(22) Filed: Apr. 13, 2015

(51) Int. Cl. B81B 7/00

(52) U.S. Cl. CPC B81B 7/0048; B81B 2201/0257; B81B 2201/0264; B81B 2207/012; B81B 2207/07

(57) ABSTRACT

A MEMS sensor component with a reduced sensitivity to internal or external stress and small spatial dimensions is provided. The component comprises a MEMS chip arranged in a cavity below a cap and elastically mounted to a carrier substrate by a connection element in a flip-chip configuration.

### TECHNICAL FIELD

The present invention refers to MEMS sensor components, e.g., to MEMS pressure sensors, MEMS barometric sensors, or MEMS microphones.

### BACKGROUND

MEMS sensor components (MEMS=Micro-Electro-Mechanical System) may comprise a MEMS chip with sensitive functional elements. Further, MEMS sensor components may comprise electric or electronic circuitry to evaluate sensor signals provided by the functional elements.

For example, a MEMS microphone comprises a flexible membrane and a rigid perforated back plate. The membrane and the back plate establish the electrodes of a capacitor. Received sound signals cause the membrane to oscillate. The oscillation of the capacitor's electrode results in an oscillating capacity. By monitoring the capacitor's capacity via electric or electronic circuitry, the sound signal is converted into an electrical signal. Electric components for monitoring the capacitors can be integrated in an ASIC chip (ASIC=Application-Specific Integrated Circuit).

A MEMS sensor component must provide housing elements to mechanically and electrically connect all circuit components and to protect sensitive elements from detrimental environmental conditions.

Further, the ongoing trend towards miniaturization demands smaller components. However, to provide good acoustic properties needed for a sufficiently good electrical signal quality, a large mechanically active region or a large back volume in the case of MEMS microphones is beneficial. Additionally, as structural parts of MEMS sensor components' housings are becoming thinner, an increasing sensitivity to internal and external mechanical stress is observed. Similar circumstances hold true for MEMS barometric pressure sensors which are even more stress sensitive. Such devices detect pressure dependent variations in the deflection of a thin membrane with a width in the sub-nanometer range. A minor stress induced deformation of the membrane can easily interfere with the deflection.

Thus, what is needed is a MEMS sensor component that allows small lateral dimensions, provides a good signal quality, and is robust against internal and/or external mechanical stress.

From U.S. Patent Application Pub. No. 2013/0193533, MEMS microphones are known. From U.S. Patent Application Pub. No. 2014/0036466, further MEMS microphones are known.

However, the need for MEMS sensor components with a reduced sensitivity to internal and external mechanical stress still exist.

### SUMMARY

A MEMS sensor component with a reduced sensitivity to stress comprises a carrier substrate, an ASIC chip embedded in the carrier substrate, a MEMS chip arranged on or above the carrier substrate, a cap arranged above the carrier substrate, a solder pad at the bottom side of the carrier substrate, an electrical interconnection at least between the ASIC chip and the solder pad, and a connection element. The cap encloses a cavity between the cap and the carrier substrate. The MEMS chip is arranged in the cavity. The connection element is an elastically deformable spring element. The connection element mechanically connects the MEMS chip in a flip-chip configuration to the carrier substrate. The connection element electrically connects the MEMS chip to the interconnection.

It is possible and it may be preferred that the connection element is a spring element or a plurality of spring elements, e.g., four, realized as patterned thin metal layer being fixed to the carrier substrate at one end and extends parallel to the carrier substrate but spaced apart from it to the other end. There may be an offset in-plane between corresponding contact points on the carrier substrate and on the MEMS chip. Thus, highly improved compliance is achieved compared to an aligned joint like a solder ball, which is also somewhat elastic in principle.

Typical materials contained in the spring element are Cu, Ni, Al or the like. Further, it is possible that the spring element consists of a metal like Cu, Ni, or Al. Typical dimensions are 5-100 μm in thickness, 10-100 μm in width, and 100-2000 μm in length. The spring constant for the assembly comprising the MEMS soldered onto typically 4 springs is lower than 100 kN/m, preferably in the order of 0.1-10 kN/m for x-, y-, and z-axis.

In such a sensor component, the MEMS chip is mechanically decoupled from any external or internal stress to which the carrier substrate is exposed as the connection element holds the MEMS chip in its steady state position without transferring a mechanical force large enough to disturb the chip's mechanical functionality. The ASIC chip is embedded in the carrier substrate. However, chips with integrated electronic circuitry are much less susceptible to mechanical forces.

The cap enclosing the cavity protects the MEMS chip and the chip's respective sensitive structural elements from detrimental external influences such as dust particles, corrosive components in the devices' surrounding atmosphere, etc. The flip-chip configuration in which the MEMS chip is mounted to the carrier substrate allows short signal routes and the flexible mounting decoupling the MEMS chip from the substrate.

Conventional flip-chip assemblies rigidly couple the chip to the substrate. Internal or external stress is directly transmitted to the chip and may result in a shift of the sensitivity of the functional structures. Thus, a temperature-induced change in sensitivity of conventional microphones can be obtained. If the temperature-induced change in sensitivity reaches the specification tolerance of a MEMS microphone, a corresponding MEMS microphone shows no stable performance. However, due to the soft support of the MEMS chip via the connection element, the present MEMS sensor component has a vastly increased temperature range of excellent performance.

It is possible that the carrier substrate comprises an organic material.

It is possible that the organic material may comprise a polymer.

In conventional MEMS sensor components, the carrier substrate needed to have a material that resists aggressive chemistry needed to form connection elements at its top side. It was found that an organic material such as a polymer is compatible with structuring steps needed for forming spring like connection element while at the same time being compatible with steps of embedding an ASIC chip in the bulk material of the carrier substrate.

It is further possible that the connection element comprises a metal and has a free-standing end.

Especially for such a connection element, complex manufacturing steps are needed as a sacrificial material needs to be arranged between the top side of the carrier substrate and the later position of the free-standing end. After arranging the metal of the connection element on the sacrificial material, the respective sacrificial material needs to be removed in order to give the needed possibility to move in all directions to the free-standing end of the connection element.

Thus, a polymer was found to be the optimal material to have an ASIC chip embedded and complex connection elements manufactured at its top side.

It is possible that the carrier substrate is a multi-layer substrate and comprises a metallization layer between two dielectric layers.

In the metallization layer, signal conductors or circuit elements such as resistive elements, capacitive elements or inductive elements or phase shifters or similar circuit elements can be structured.

Accordingly, it is possible that the MEMS sensor component comprises such an additional circuit element embedded in the multi-layer substrate. It is further possible that an additional circuit element is an active circuit element, e.g., as part of an additional ASIC circuit or as a part of circuitry not integrated in the ASIC chip.

The additional circuit element may comprise a structured metallization in the metallization layer, in an additional metallization layer above or below the metallization layer or in additional metallization layers above and below the metallization layer. Inductive elements can be realized by coil shaped conductor stripes within the same metallization layer. Capacitive elements can comprise electrodes existing in different metallization layers stacked one above the other.

Via connections can be utilized to electrically connect different circuit elements in different metallization layers and/or connection pads on the top side of the carrier substrate and/or the solder pad at the bottom side of the carrier substrate.

It is possible that the cap seals the cavity.

If the MEMS sensor component establishes a MEMS microphone, then a back volume acoustically decoupled from the microphone's environment is needed to prevent an acoustic short circuit. This back volume may at least partially be arranged in the cavity and the sealing cap prevents sound signals from contaminating the microphone's interior pressure levels.

However, it is possible that the cavity has an opening, e.g., a sound opening. The sound entry opening may be realized by a hole. The hole may be arranged in the carrier substrate or in a segment of the cap. The sound entry is needed to conduct acoustic signals to the functional element of the MEMS chip.

Thus, it is possible that the cavity comprises at least a segment that is sufficiently sealed from the component's environment.

Accordingly, it is possible that the cap or the carrier substrate comprises an opening, e.g., a sound entry opening which may be realized as a hole.

It is possible that the MEMS sensor component comprises a soft fixation element in addition to the connection element. The soft fixation element connects the MEMS chip to the carrier substrate and/or to an inner surface of the cap.

It is possible that the soft fixation component comprises a soft laminate foil or a gel.

It is possible that the soft fixation component comprises a silicone-type gel comprising silicone.

The soft fixation component, e.g., in the form of a silicone-type gel, may support the connection element in holding the MEMS chip in its steady state position without exposing the MEMS chip to internal or external stress.

It is possible that the soft fixation component fills at least a part of the volume between the MEMS chip and the carrier substrate or between the MEMS chip and the cap.

The soft fixation component improves the mechanical damping and the impact shock robustness without the danger of contaminating the MEMS chip's functional elements. The soft fixation element is compatible with most sensor types, such as sensors with springs used to decouple the MEMS chip. The soft fixation component may mainly have the viscose properties of a fluid without the possibility to transmit static forces but with the possibility to remain at its steady state position. Thus, the MEMS chip's sensitive functional elements are not jeopardized.

Accordingly, it is possible that the MEMS chip comprises functional structures, e.g., deflection sensors, membranes, rigid perforated back plates, etc. It is especially possible that the MEMS chip is selected from a microphone chip, a pressure sensor chip, and a barometric sensor chip.

It is possible that a cavity with or without a back volume within the MEMS chip is filled by material of the soft fixation element.

It is possible that the cap comprises an edge and a hole in the edge.

It is also possible that the cap comprises a side portion and a hole in the side portion.

Further, it is possible that the cap comprises a first segment at a first distance from the carrier substrate and a second segment in a second distance from the carrier substrate different from the first distance. Then, a hole is formed in the segment closer to the carrier substrate.

Such embodiments have a hole, e.g., a sound entry hole, in the cap. However, the sensor component can—at least temporarily—be arranged upside down on an auxiliary foil during certain manufacturing steps without the risk of closing the hole. Especially when the auxiliary foil has an adhesive tape to hold the component tightly, the hole cannot be filled by the adhesive.

### BRIEF DESCRIPTION OF THE DRAWINGS

The MEMS sensor component, its basic working principles and a selected but not limiting set of preferred embodiments are shown in the accompanying figures. In detail,

FIG. 1 shows a basic construction of the MEMS sensor component;

FIG. 2 shows an embodiment of a MEMS microphone;

FIG. 3 shows an alternative embodiment of the MEMS microphone;

FIG. 4 shows a MEMS sensor component with a back volume closed by a lid;

FIG. 5 shows an embodiment with a hole in the cap;

FIG. 6 shows an embodiment with a soft fixation element supporting the connection element in holding the MEMS chip;

FIG. 7 shows an embodiment where a large volume of the cavity is filled by the soft fixation element;

FIG. 8 shows an embodiment where a soft fixation element is arranged between the cap and the top side of the MEMS chip and where a hole is arranged in an edge region of the cap;

FIG. 9 shows an embodiment with a stepped cap comprising different segments in a different distance from the top side of the carrier substrate;

FIG. 10 shows an embodiment with an integrated capacitive element;

FIG. 11 shows an embodiment with an integrated inductive element; and

FIG. 12 shows an embodiment with an additional circuit element.

### DETAILED DESCRIPTION OF ILLUSTRATIVE EMBODIMENTS

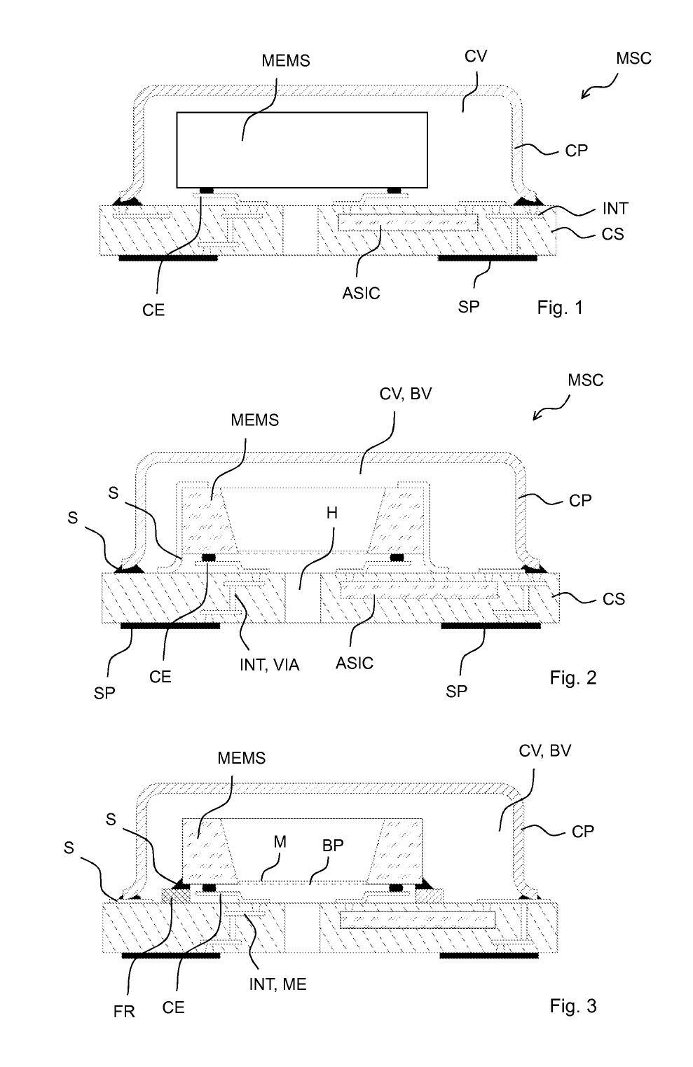

FIG. 1 shows a MEMS sensor component MSC with a MEMS chip MEMS arranged above a carrier substrate CS. Two or more connection elements CE are created at the top side of the carrier substrate CS to electrically connect and mechanically support the MEMS chip MEMS. The connection elements CE comprise a segment directly connected to the carrier substrate CS and an additional segment at a free-standing end directly connected to a solder ball at the bottom side of the MEMS chip MEMS.

Further, an ASIC chip ASIC is embedded in the carrier substrate CS. At the bottom side of the carrier substrate CS, at least two solder pads SP are arranged provided for connecting the MEMS sensor component MSC to an external circuit environment. An interconnection INT comprises a plurality of conductor segments and electrically connects the MEMS chip MEMS, the ASIC chip ASIC and the one or the plurality of solder pads SP.

A cap CP is arranged above the carrier substrate CS and encloses a cavity CV in which the MEMS chip MEMS is arranged.

The embodiment of the MEMS sensor component MSC shown in FIG. 1 comprises a hole through the carrier substrate CS via which the MEMS chip and its sensitive functional structures, respectively, are connected to the components' environment.

FIG. 2 shows an embodiment of a MEMS sensor component being a MEMS microphone. The microphone has the MEMS chip arranged over a hole H in the carrier substrate CS which may work as a sound entry hole. The main portion of the cavity CV acts a back volume BV to prevent an acoustic short circuit. To separate the back volume BV from sound pressure surrounding the microphone, an outer seal S closes possible gaps between the cap CP and the carrier substrate CS. An inner seal S closes possible gaps between the MEMS chip MEMS and the carrier substrate CS. Thus, sound pressure is only applied to the functional structures of the MEMS chip MEMS.

FIG. 3 shows an alternative embodiment of a MEMS microphone where the MEMS chip is sealed with an inner seal S to a frame structure FR arranged on the top side of the carrier substrate. Thus, the membrane M and the back plate BP are only exposed to sound signals entering the hole from one side. Nearly the whole volume of the cavity CV acts as a back volume BV which is beneficial for good acoustic properties while minimizing the overall volume of the microphone. The frame structure FR or at least the material of the inner seal S may comprise a soft material that—in addition to the connection element CE—acts as a shock absorber and mechanically decouples the MEMS chips from internally or externally induced stress while maintaining the MEMS chip MEMS at a steady state position.

A further metallization ME can be arranged on the top side of the carrier substrate. If the cap CP comprises an electrically conductive material, the cap can be connected to a ground potential via the metallization ME to improve the electrical shielding.

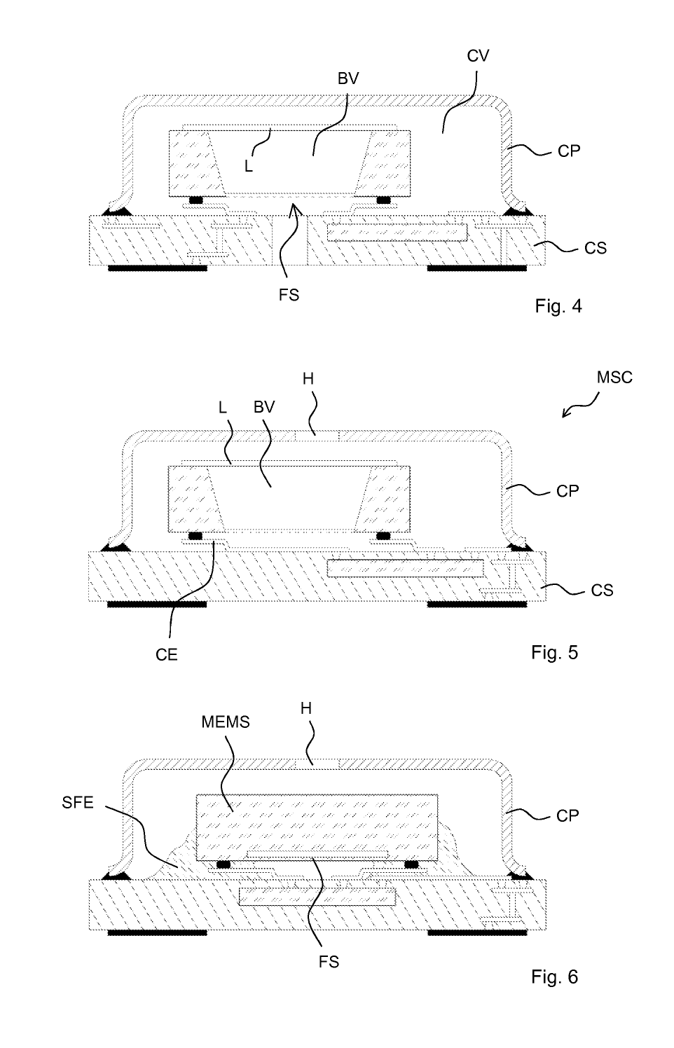

FIG. 4 shows an embodiment of a MEMS microphone where the back volume BV is arranged within an interior section of the MEMS chip and where a lid L separates the back volume BV from other sections of the cavity CV. Signals received from the microphone's environment can be obtained via a hole in the carrier substrate CS. Apart from the functional structures FS of the MEMS chip, other surfaces within the cavity CV but not within the back volume BV are exposed to the external signals. Thus, the cavity CV can comprise further sensor components such as further MEMS chips to gain information about the components' environment.

FIG. 5 shows an embodiment where a hole H is arranged in the cap CP. The back volume BV is sealed by a lid L. No hole needs to be structured through the carrier substrate CS.

FIG. 6 shows an embodiment where an additional soft fixation element supports the MEMS chip MEMS. The soft fixation element may further prevent particles entering the cavity through the hole from getting in direct contact with functional structures FS. However, due to the viscous properties of the soft fixation element, information concerning the components' environment, e.g., atmospheric pressure, can be gained without jeopardizing the mechanical functionality of the functional structures. Further, the MEMS sensor component shown in FIG. 6 could be immersed into a liquid, e.g., during manufacturing steps or during normal operation. Thus, the component can be used as a depth finder for underwater operations.

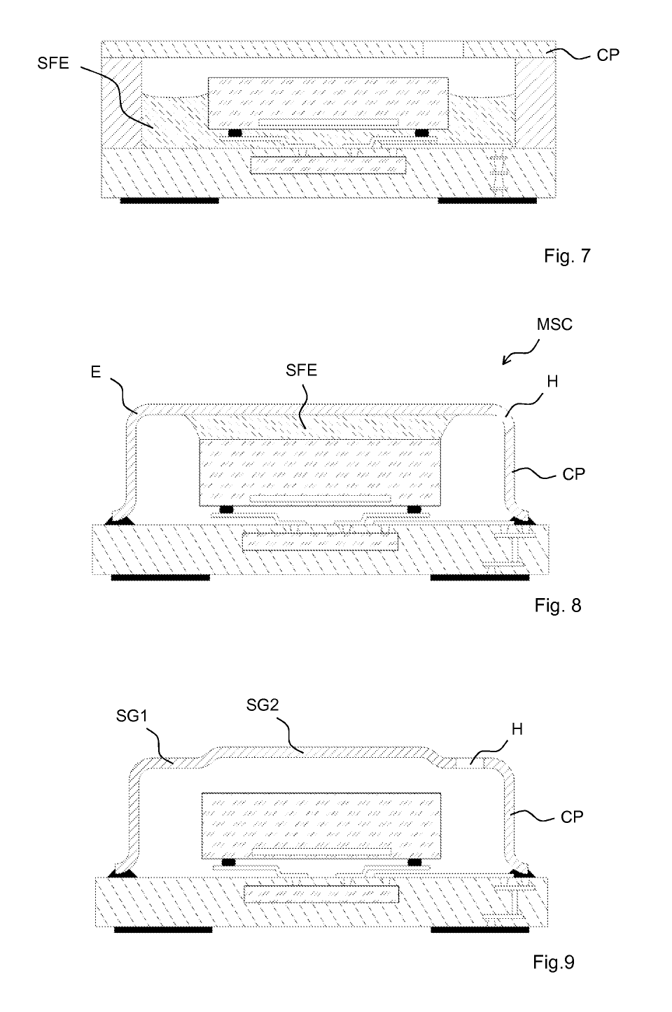

FIG. 7 shows another embodiment of a MEMS sensor component where major parts of the cavity are filled with the soft fixation element where the soft fixation element even touches the functional structures of the MEMS chip. Thus, even if the MEMS chip comprises functional structures sensitive to a corrosive environment, the component can be operated in such a corrosive environment.

FIG. 8 shows an embodiment where the soft fixation element supports the MEMS chip from a position opposite the carrier substrate.

A hole H is arranged in an edge region E of the cap CP. This allows new manufacturing steps where the component or a part of the component, such as the cap CP, is arranged upside down on an auxiliary carrier such as an adhesive auxiliary foil. The adhesive from the auxiliary carrier cannot close the hole H. Then, the soft fixation element can be applied to the inner side of the cap CP when the cap is arranged upside down. Thereafter, the cap CP including the soft fixation element SFE can be pulled over the MEMS chip arranged on the carrier substrate in an upright position.

FIG. 9 shows an embodiment where the cap CP has a first segment SG1 at a first distance from the top side of the carrier substrate and a second segment SG2 at a second distance from the top side of the carrier substrate. The hole H can be arranged in the segment nearer to the carrier substrate. Thus, the cap CP can be arranged upside down on an auxiliary carrier without direct contact to the hole H.

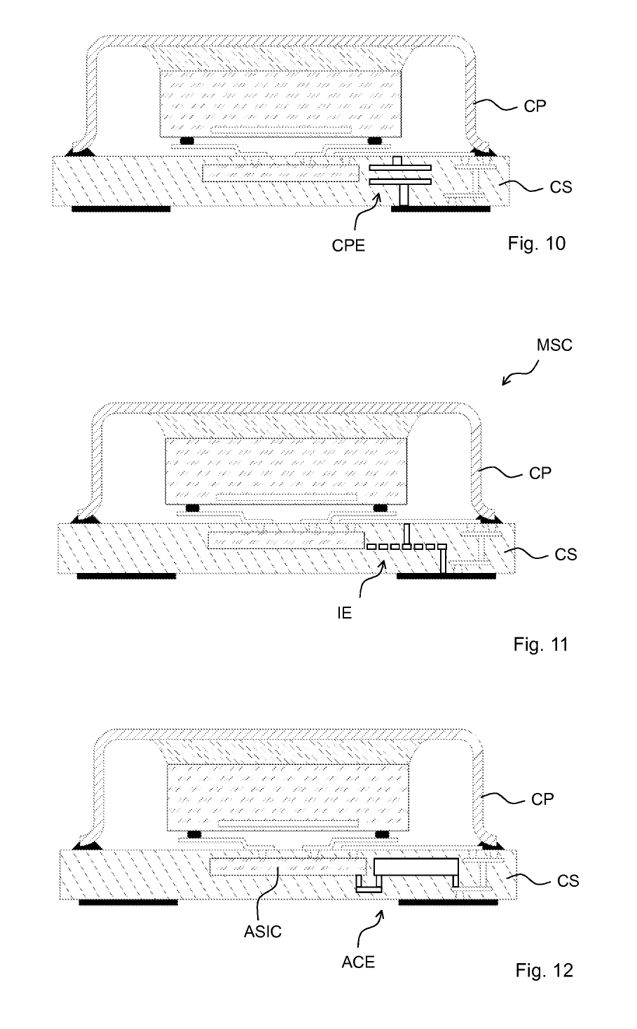

FIG. 10 shows the possibility of arranging additional circuit elements such as passive circuit elements, e.g., a capacitance element CPE, in a multi-layered structure of the carrier substrate CS. Two conductor segments establish the electrodes of the capacitor electrically connected to the interconnection.

FIG. 11 shows the possibility of integrating an inductive element IE in a multi-layered carrier substrate.

FIG. 12 shows the possibility of embedding additional circuit element ACE, e.g., additional integrated circuit chips, in the multi-layered substrate.

The MEMS sensor component is not limited to the features stated above or to the embodiments shown by the figures. Components comprising further circuit elements or connection elements are also comprised by the present invention.

What is claimed is:

1. A MEMS sensor component, comprising:
a carrier substrate;
an ASIC chip embedded in the carrier substrate;
a MEMS chip arranged on or above the carrier substrate;
a cap arranged above the carrier substrate, wherein the cap encloses a cavity and the MEMS chip is arranged in the cavity;
a solder pad at a bottom side of the carrier substrate;
an electrical interconnection between the ASIC chip and the solder pad; and
a connection element comprising an elastically deformable spring element, wherein the connection element mechanically connects the MEMS chip in a flip-chip configuration to the carrier substrate and wherein the connection element electrically connects the MEMS chip to the interconnection.

2. The MEMS sensor component according to claim 1, wherein the carrier substrate comprises an organic material.

3. The MEMS sensor component according to claim 2, wherein the carrier substrate comprises a polymer.

4. The MEMS sensor component according to claim 1, wherein the connection element comprises a metal and has a freestanding end.

5. The MEMS sensor component according to claim 1, wherein the carrier substrate comprises a multilayer substrate that includes a metallization layer between two dielectric layers.

6. The MEMS sensor component according to claim 5, further comprising an additional circuit element embedded in the multilayer substrate, the additional circuit element comprising an active or a passive circuit element.

7. The MEMS sensor component according to claim 6, wherein the additional circuit element comprises a resistive element, an inductive element, or a capacitive element, the additional circuit element comprising structured metallizations in the metallization layer.

8. The MEMS sensor component according to claim 1, wherein the cap seals the cavity.

9. The MEMS sensor component according to claim 1, wherein the cap or the carrier substrate comprises an opening.

10. The MEMS sensor component according to claim 1, further comprising a soft fixation element mechanically connecting the MEMS chip to the carrier substrate.

11. The MEMS sensor component according to claim 10, wherein the soft fixation element comprises a soft laminate foil or a gel.

12. The MEMS sensor component according to claim 11, wherein the soft fixation element comprises a silicone-type gel.

13. The MEMS sensor component according to claim 10, wherein the soft fixation element fills at least a part of a volume between the MEMS chip and the carrier substrate or between the MEMS chip and the cap.

14. The MEMS sensor component according to claim 10, wherein the soft fixation element mechanically connects the MEMS chip to the cap or to the carrier substrate.

15. The MEMS sensor component according to claim 10, wherein the connection element is embedded in the soft fixation element.

16. The MEMS sensor component according to claim 1, wherein the MEMS chip comprises functional structures.

17. The MEMS sensor component according to claim 16, wherein the MEMS chip comprises a microphone chip, a pressure sensor chip, or a barometric sensor chip.

18. The MEMS sensor component according to claim 1, wherein the cap comprises an edge and a hole in the edge.

19. The MEMS sensor component according to claim 1, wherein the cap comprises a side portion and a hole in the side portion.

20. The MEMS sensor component according to claim 1, wherein the cap comprises a first segment in a first distance from the carrier substrate and a second segment in a second distance from the carrier substrate different from the first distance, a hole being formed in the segment closer to the carrier substrate.
